(19) United States
(12) Patent Application Publication
(10) Pub. No.: US 2010/0037827 A1
(43) Pub. Date: Feb. 18, 2010

(54) CVD Device with Substrate Holder with Differential Temperature Control

(76) Inventor: Johannes Kaeppeler, Wuerselen (DE)

Correspondence Address: ST. ONGE STEWARD JOHNSTON & REENS, LLC, 986 BEDFORD STREET, STAMFORD, CT, 06905-5619, US

(21) Appl. No.: 12/551,189

(22) Filed: Aug. 31, 2009

Related U.S. Application Data
(63) Continuation-in-part of application No. 10/751,390, filed on Jan. 5, 2004, now abandoned.
Application No. 10/751,390 is a continuation of application No. PCT/EP02/04405, filed on Apr. 22, 2002.

(30) Foreign Application Priority Data
Jul. 4, 2001 (DE) 101 32 448.0

(51) Int. Cl. C23C 16/46; C23C 16/00

(52) U.S. Cl. 118/725

(57) ABSTRACT

The invention relates to a device for depositing especially crystalline layers on an especially crystalline substrate, comprising a high-frequency heated substrate support from a conductive material on which the substrate is two-dimensionally supported, and which comprises a zone of higher conductivity. The system is specifically characterized in that the higher conductivity zone is associated with the surface of support of the substrate and substantially corresponds to the area occupied by the substrate. Further, the zone on which the substrate rests heats up more than the substrate surface surrounding the substrate.

### CROSS-REFERENCE TO RELATED APPLICATIONS

This application is a continuation-in-part of U.S. patent application Ser. No. 10/751,390 filed Jan. 5, 2004, which is a continuation of International Patent Application No. PCT/EP02/04405 filed Apr. 22, 2002 which designates the United States and claims priority of German Application No. 101 32 448.0 filed Jul. 4, 2001.

### FIELD OF THE INVENTION

The invention relates to a device for depositing crystalline layers on a crystalline substrate, having a high-frequency-heated substrate holder made from conductive material for holding the substrate with surface-to-surface contact, which substrate holder has zones of higher electrical conductivity.

### BACKGROUND OF THE INVENTION

DE 199 40 033 describes a CVD device of this type. This document describes a device for depositing silicon carbide layers in a reactor, the walls of which form a flow passage which is heated on all sides. In this case, thin plates of inert material, for example, tantalum, molybdenum or tungsten, are to be fitted in the flow passage and in particular in the region of the substrate holder, in order to locally influence the high-frequency coupling and thereby the introduction of energy.

Considerable radiation losses occur at the surface of the substrate holder of devices which are used to deposit crystalline layers on in particular crystalline substrates and in which only the substrate holder is heated, whereas the remaining reactor walls are not actively heated. The level of the radiation losses is highly dependent on the quality of the surface of the substrate holder. The substrate holder is generally only partially occupied by substrates. On account of manufacturing-related inaccuracies and/or thermal distortion, gaps which have an insulating effect are formed between the substrate and the surface of the substrate holder.

Still further, devices in which the substrates rest on separate substrate bearing disks are located in cutouts in the substrate holder. In these devices, the substrate bearing disks are located on a gas bearing which rotates, so that the substrate holder bearing disks are driven in rotation. This has the consequence that the substrate temperature is lower than the surface temperature of the substrate holder in the immediate vicinity of the substrate. This temperature difference has an adverse effect on the layer growth characteristics.

### SUMMARY OF THE INVENTION

Accordingly, what is desired then is a system and method that provides a coupling between the substrate and a substrate bearing disk that substantially allows the substrate to be maintained at the temperature of the bearing disk.

It is further desired to provide a system and method that addresses the differing temperature differential of known systems that develops in the immediate vicinity of the substrate.

One advantageous embodiment of invention is therefore based on the object of providing measures for making the temperature profile in the region of the substrate holder or in the layer of gas immediately above it more uniform.

That particular object is achieved in which the zone of higher conductivity is associated with the supported surface of the substrate. It is proposed therein for the zone of higher conductivity to substantially correspond to the area taken up by the substrate. Furthermore, it is provided that the zone is formed by a piece made of metal. It is advantageous if each of a multiplicity of substrates resting on the substrate holder is located above a zone of higher electrical conductivity, which zone has the same surface dimensions as the substrate. This ensures that the substrate is located on a zone of the substrate holder which is hotter than the substrate holder surface surrounding the substrate. This configuration makes it possible to compensate for heat transfer losses. Furthermore, this configuration also has the associated advantage that by suitable over-dimensioning of the zones of higher electrical conductivity, it is possible to generate a temperature profile in which the zones of the substrate holder on which the substrates are located are hotter than the surface of the substrate holder surrounding the substrates. It is considered particularly advantageous for the substrate holder to have one or more substrate bearing disks, which in particular are mounted on rotary gas bearings and entirely formed of a material having a higher electrical conductivity than the material surrounding the bearing disk. However, in order to minimize the dimensions of the substrate bearing disk, there is also provision for the substrate bearing disk to be located on a gas bearing in a bearing recess of the substrate holder and for the insert piece or the zone of higher electrical conductivity to be associated with the base of the bearing recess. Suitable materials for the insert piece are molybdenum, tantalum or tungsten. The substrate holder may further be associated with or even surrounded by a high-frequency coil. This may be, for example, a tunnel reactor. Alternatively, however, the substrate holder may also be configured as a cylindrical disk which is disposed above a high-frequency coil formed as a planar coil. With this type of “planetary reactor”, the substrate holder disk itself can rotate. The individual substrate bearing disks, referred to as planets, in turn rotate about their own axes. To absorb the centrifugal forces which occur as a result of the substrate holder rotation and act on the substrate bearing disks, it is possible for the bearing recesses to provide central bearing pins which engage in associated bearing recesses in the substrate bearing disks.

In another advantageous embodiment, a device for depositing crystalline layers on a substrate is provided comprising a substrate holder forming a bearing recess into which a gas flow passage opens and a circular substrate bearing disk rotating on a gas bearing in a centered position inside the bearing recess. The system is provided such that the gas bearing is provided by means of a gas flow, which flows through the gas flow passage. The device further comprises a ring slit between the circumferential surface of the substrate bearing disk and the corresponding surface of the bearing recess is flushed by the gas flow, a substrate rests on the substrate bearing disk in such a manner as to fill the surface area and a high frequency heater heating said substrate holder and said substrate bearing disk by electrical conduction thereby heating the substrate. The device is further provided such that the substrate holder is entirely formed of a first material exhibiting a first electrical conductivity, the substrate bearing disk is entirely formed of a second material exhibiting a second electrical conductivity and said second electrical conductivity is higher than said first electrical conductivity. The device is still further provided such that when being heated the surface temperature (t₁) of the substrate bearing disk covered by the substrate is greater than the surface temperature (t₂) of the surface of the substrate holder adjacent the bearing recess, not covered by a substrate, the substrate temperature exceeds the temperature of the surface surrounding the substrate and the gas flow through the ring slit forms an insulation zone between the substrate holder and the hotter substrate bearing disk to minimize heat transport from the substrate bearing disk to the substrate holder.

In still another advantageous embodiment, a device for depositing crystalline layers on a substrate is provided comprising a substrate holder forming a bearing recess into which a gas flow passage opens the substrate holder formed of a first material that exhibits a first electrical conductivity. The device further comprises a gas flow entering the bearing recess and forming a gas bearing and a substrate bearing disk rotating on the gas bearing within the bearing recess, the substrate bearing disk formed of a second material that exhibits a second electrical conductivity, where the second electrical conductivity is higher than the first electrical conductivity. The device still further comprises a channel positioned between the substrate bearing disk and an inner surface of the bearing recess. The device is provided such that the gas flow moving through the channel and exiting the channel at an upper surface of the substrate bearing disk and an upper surface of the substrate holder forms an insulation zone in the form of a gas barrier between the substrate bearing disk and the substrate holder to substantially eliminate heat transfer from the substrate bearing disk to the substrate holder. The device also comprises a substrate positioned on the substrate bearing disk, the substrate substantially corresponding to an upper surface area of the upper surface of the substrate bearing disk and a high frequency heater positioned in the vicinity of the substrate bearing disk. The device is further provided such that a first temperature (t₁) of the substrate bearing disk is higher than a second temperature (t₂) of the substrate holder which is immediately adjacent to and across the gas barrier from the substrate bearing disk. Finally, the device is provided such that a third temperature (t₃) of the substrate substantially corresponds to the first temperature (t₁) of the substrate bearing disk.

It is understood that, in one advantageous embodiment, the substrate bearing disk may comprise, for example, a metal, such as molybdenum, tantalum or tungsten. It is further understood that the substrate bearing disk may comprise a plurality of substrate bearing disks that are arrayed or disposed in a planetary fashion on the substrate holder.

Additionally, in another advantageous embodiment, the high frequency heater may comprise a High Frequency (HF) coil disposed below the substrate holder.

Still further, the reactor with which the substrate holder is associated may, in still another advantageous embodiment, comprise a cold-wall reactor, the walls of which are heated only by the radiation of the heated substrate holder. The reactor, in yet another advantageous embodiment, may further comprise a tunnel reactor.

### BRIEF DESCRIPTION OF THE DRAWINGS

Exemplary embodiments of the invention are explained below with reference to appended drawings, in which:

FIG. 1 shows, a plan view, a rotationally driven substrate holder which is in the form of a circular disk and has substrate bearing disks arranged in planetary fashion and rotating about their own axes as they rest on a gas bearing,

FIG. 2 shows a section on line II-II in FIG. 1,

FIG. 3 shows a partial illustration, corresponding to FIG. 2, of a variant,

FIG. 4 shows an illustration corresponding to FIG. 3 of a further variant,

FIG. 5 shows a cut-away, perspective illustration of a tunnel reactor, and

FIG. 6 shows a section on line VI-VI in FIG. 5.

### DETAILED DESCRIPTION OF THE INVENTION

Referring now to the drawings, wherein like reference numerals designate corresponding structure throughout the views.

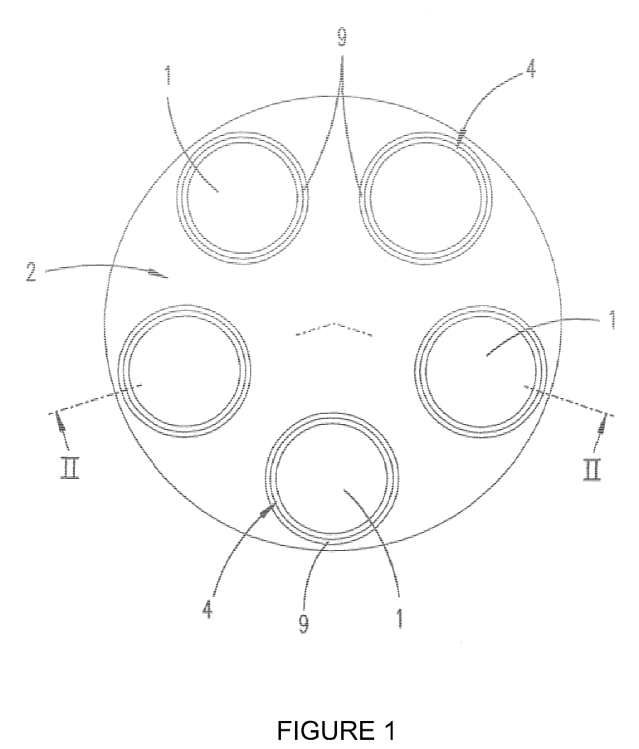

The substrate holder 2 illustrated in FIGS. 1-4 comprises a block of graphite which is in the form of a cylindrical disk and is located in a reactor, driven in rotation about its own axis. The reactive gases are introduced into the process chamber through a feed line disposed above and in the center of the substrate holder. The walls of this process chamber are not heated. They are only heated by the radiation of the substrate holder 2, which is heated from below by means of an HF coil 5. The result of this is that there is a temperature drop inside the process chamber from the substrate holder 2 toward the process chamber walls (not shown). The reactive gases which are introduced into the process chamber and which may be trimethyl-gallium, trimethyl-indium, arsine and/or phosphine, partially decompose in the gas phase and on the substrate surface. On the substrate surface, the decomposition products form a semiconductor layer comprising III-V material. Since the decomposition reaction, at least of the III starting materials, is to take place substantially only on the substrate surface and not on the adjacent substrate holder, it is necessary for the temperature of the substrate surface to be higher than the temperature of the surface of the substrate holder area which adjoins the substrate. Accordingly, the invention deals with a refinement of a known MOCVD reactor.

To bring the temperature of the substrate 1 at least to the temperature corresponding to the temperature of the surface of the substrate holder 2 surrounding the substrate, there is provision for insert pieces 3 made from metal to be placed inside the substrate holder 2 beneath the substrate 1. Suitable metals are tungsten, tantalum or preferably molybdenum. This metal inlay, which extends beneath the substrate 1 substantially covering the surface, causes the high frequency emitted by the HF coil 5 to be more strongly coupled. This leads to increased conversion of heat in the insert piece 3. As a result, the substrate 1, which is located almost directly above the insert piece 3, is heated to a greater extent than the substrate holder surrounding the substrate 1.

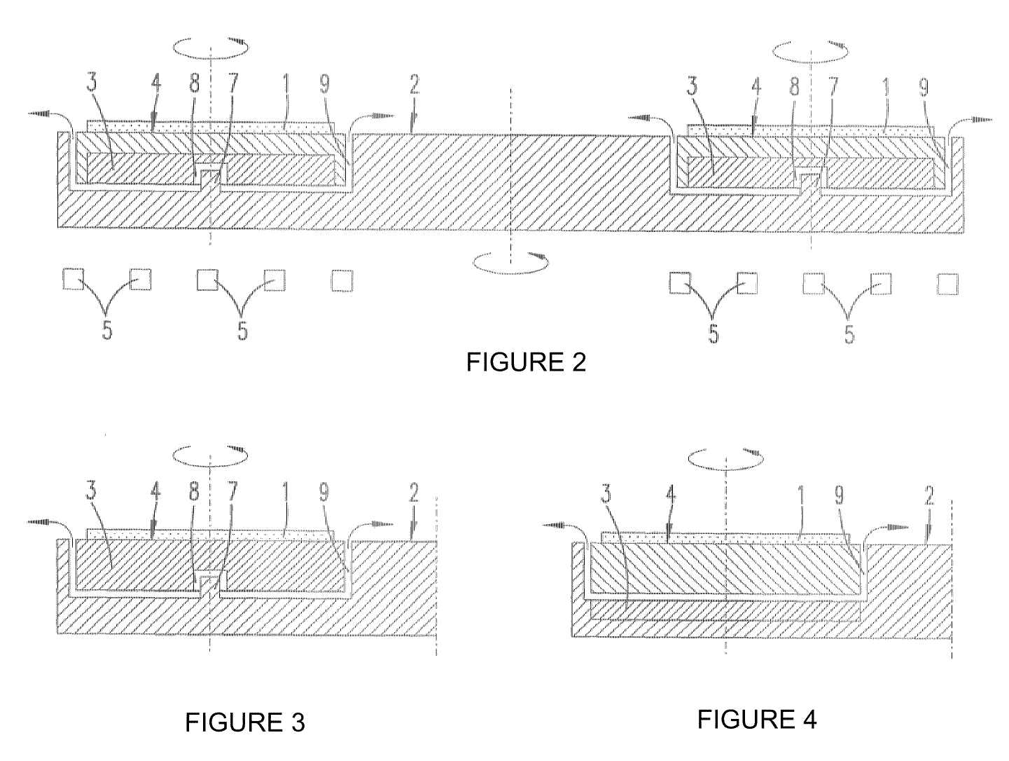

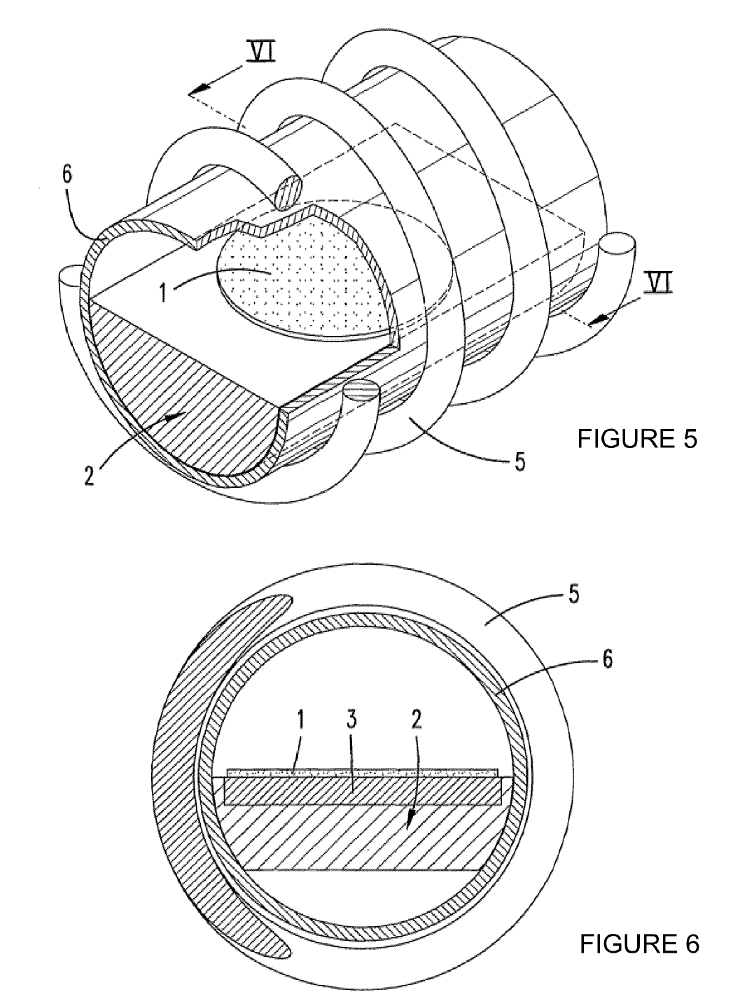

In the exemplary embodiment illustrated in FIG. 2, the substrate 1 rests on a substrate bearing disk 4 in such a manner as to virtually fill the surface area. The substrate bearing disk 4 likewise consists of graphite. However, on its underside, which is disposed opposite the base of the bearing recess 9, it has an insert piece 3 made from molybdenum. Apart from a narrow edge strip, the size of the insert piece 3 corresponds to the substrate bearing disk 4, which is in the form of a circular disk. To mount the substrate bearing disk 4 in a centered position, the insert piece 3 has a bearing opening 8 in its center. A bearing pin 7 which projects from the center of the base of the bearing recess 9 engages in the bearing opening 8 in order to hold the substrate bearing disk 4 rotating on a gas bearing in a centered position when the entire substrate holder 2 is rotating about its own axis. The substrate bearing disk 4 is driven in a rotation in a known way by means of a gas flow which flows through passages (not shown) in the substrate holder 2. These passages open out into helical grooves in the base of the bearing recess 9 and cause the substrate bearing disk 4 to rotate through viscous forces.

In the exemplary embodiment illustrated in FIG. 3, the entire substrate bearing disk 4 is configured as a metal block, such as for example, molybdenum, tantalum or tungsten. A gas bearing is provided by means of a gas flow via bearing opening 8. For example, gas enters into holes of the bottom of the bearing recess 9, which is part of the substrate holder 2, which may consist of graphite.

The gas bearing operates to lift the substrate bearing disk 4 and rotates it in a centered (central) position inside the bearing recess 9. A ring slit (illustrated as the opening between substrate bearing disk 4 and the inside wall of bearing recess 9) is formed between the circumferential surface of the substrate bearing disk 4 and the corresponding side wall of the bearing recess 9 through which a gas flow is flushed (illustrated as arrows exiting the ring slit). In one advantageous embodiment, the gases providing the gas bearing may comprise, for example, H₂, N₂ or any other inert gas or Nobel gas. This allows a temperature profile to be developed, where the surface temperature T₁ of the substrate bearing disk 4 is higher that the surface temperature T₂ of the surface of the substrate holder 2 adjacent to the bearing recess 9. It should be noted that the surface of the adjacent substrate holder 2 is not covered by substrate 1. Heat (or energy) is transferred exclusively from the substrate bearing disk 4 to the substrate 1 such that, the substrate 1 temperature exceeds the temperature of the surface surrounding the substrate 1.

As stated above, a ring slit is positioned between the substrate bearing disk 4 and the substrate holder 2, such that, there is no solid state contact between the substrate bearing disk 4, which comprises a material with relatively high electrical conductivity, and the substrate holder 2, which comprises a material with relatively low electrical conductivity. The gas flow through the ring slit forms an insulation zone, e.g., the area between the substrate holder 2 and the hotter substrate bearing disk 4 and an area extending above the ring slit (shown as arrows exiting the ring slit). The energy transported from the substrate bearing disk 4 to the substrate holder 2 is minimized (virtually eliminated) due to the gas exiting (flushing) upward from and out of the ring slit. This configuration results in a temperature profile, which has a steep gradient between the lower temperature zone (e.g. the substrate holder 2) and the higher temperature zone (the substrate bearing disk 4) where the latter is substantially completely covered by the substrate 1.

In the exemplary embodiment illustrated in FIG. 4, the substrate bearing disk 4 is made entirely from graphite. In this configuration, it is possible to dispense with the bearing pin 7, since the mass of the substrate bearing disk 4 is lower than that in the exemplary embodiment shown in FIG. 3. In the exemplary embodiment shown in FIG. 4, an insert piece 3 made from molybdenum is located beneath the substrate bearing disk 4 in the substrate holder 2, with an approximately identical surface area. The surface of the insert piece 3, which is uncovered at the top, forms the base of the bearing recess 9. The passages through which the gas flows in order to maintain the rotationally driving gas bearing, can run through the molybdenum block 3.

As can be seen from FIG. 6, an insert piece 3 is positioned in a positively locking manner inside a cutout in the substrate holder 2, virtually precisely beneath the substrate 1. In this exemplary embodiment, the substrate 1 rests directly on the surface of the insert piece 3. The surface of the insert piece 3, which insert piece may consist of molybdenum, may, like the surface of the substrate holder surrounding the insert piece 3, be coated in a suitable way.

With the configurations which have been described above and are illustrated in the drawings, it is possible to disproportionately increase the substrate temperature compared to the surface of the substrate holder 2 surrounding the substrate. This may even reduce parasitic growth outside the substrate surface.

All features disclosed are (inherently) pertinent to the invention. The disclosure content of the associated/appended priority documents (copy of the prior application) is hereby incorporated in its entirety in the disclosure of the application, partly with a view to incorporating features of these documents in claims of the present application.

What is claimed is:

1. A device for depositing crystalline layers on a substrate comprising:
a substrate holder forming a bearing recess into which a gas flow passage opens;
a circular substrate bearing disk rotating on a gas bearing in a centered position inside the bearing recess,
wherein the gas bearing is provided by means of a gas flow, which flows through the gas flow passage;
a ring slit between the circumferential surface of the substrate bearing disk and the corresponding surface of the bearing recess is flushed by the gas flow;
a substrate rests on the substrate bearing disk in such a manner as to substantially fill the surface area of the bearing disk;
a high frequency heater heating said substrate holder and said substrate bearing disk by electrical conduction thereby heating the substrate;
wherein the substrate holder is entirely formed of a first material exhibiting a first electrical conductivity, the substrate bearing disk is entirely formed of a second material exhibiting a second electrical conductivity and said second electrical conductivity is higher than said first electrical conductivity; and
wherein when being heated the surface temperature (t₁) of the substrate bearing disk covered by the substrate is greater than the surface temperature (t₂) of the surface of the substrate holder adjacent the bearing recess, not covered by a substrate, the substrate temperature exceeds the temperature of the surface surrounding the substrate and the gas flow through the ring slit forms an insulation zone between the substrate holder and the hotter substrate bearing disk to minimize heat transport from the substrate bearing disk to the substrate holder.

2. The device according to claim 1 wherein the substrate bearing disk comprises metal.

3. The device according to claim 2 wherein the metal is selected from the group consisting of: molybdenum, tantalum or tungsten.

4. The device according to claim 1 further comprising a plurality of substrate bearing disks disposed in a planetary fashion on said substrate holder.

5. The device according to claim 1 wherein said high frequency heater comprises a HF coil.

6. The device according to claim 5 wherein said substrate holder is disposed above the HF coil.

7. The device according to claim 1 further comprising a reactor with which the substrate holder is associated, said reactor being a cold-wall reactor, the walls of which are heated only by the radiation of the heated substrate holder.

8. The device according to claim 7 wherein said reactor comprises a tunnel reactor.

9. The device according to claim 1 wherein the gas flow comprises a gas selected from the group consisting of: H₂, N₂, an inert gas, a Nobel gas and combinations thereof.

10. A device for depositing crystalline layers on a substrate comprising:
a substrate holder forming a bearing recess into which a gas flow passage opens said substrate holder formed of a first material that exhibits a first electrical conductivity;
a gas flow entering the bearing recess and forming a gas bearing;
a substrate bearing disk rotating on the gas bearing within the bearing recess, said substrate bearing disk formed of a second material that exhibits a second electrical conductivity, where the second electrical conductivity is higher than the first electrical conductivity,
a channel positioned between said substrate bearing disk and an inner surface of said bearing recess;
said gas flow moving through said channel and exiting said channel at an upper surface of said substrate bearing disk and an upper surface of said substrate holder to form an insulation zone in the form of a gas barrier between said substrate bearing disk and said substrate holder to substantially eliminate heat transfer from said substrate bearing disk to said substrate holder;
a substrate positioned on said substrate bearing disk, said substrate substantially corresponding to an upper surface area of the upper surface of said substrate bearing disk;
a high frequency heater positioned in the vicinity of said substrate bearing disk;
wherein a first temperature (t₁) of the substrate bearing disk is higher than a second temperature (t₂) of the substrate holder which is immediately adjacent to and across the gas barrier from said substrate bearing disk; and
wherein a third temperature (t₃) of the substrate substantially corresponds to the first temperature (t₁) of the substrate bearing disk.

11. The device according to claim 10 wherein the substrate bearing disk comprises a metal selected from the group consisting of: molybdenum, tantalum or tungsten.

12. The device according to claim 10 further comprising a plurality of substrate bearing disks disposed in a planetary fashion on said substrate holder.

13. The device according to claim 10 wherein said high frequency heater comprises a HF coil.

14. The device according to claim 13 wherein said substrate holder is disposed above the HF coil.

15. The device according to claim 10 further comprising a reactor with which the substrate holder is associated, said reactor being a cold-wall reactor, the walls of which are heated only by the radiation of the heated substrate holder.

16. The device according to claim 15 wherein said reactor comprises a tunnel reactor.

17. The device according to claim 10 wherein the gas flow comprises a gas selected from the group consisting of: H₂, N₂, an inert gas, a Nobel gas and combinations thereof.
